(19) United States
(12) Patent Application Publication
(10) Pub. No.: US 2016/0021786 A1
(43) Pub. Date: Jan. 21, 2016

(54) ELECTRONIC APPARATUS

(71) Applicant: Kabushiki Kaisha Toshiba, Tokyo (JP)

(72) Inventor: Yukihiko Hata, Hamura Tokyo (JP)

(21) Appl. No.: 14/688,850

(22) Filed: Apr. 16, 2015

(30) Foreign Application Priority Data
Jul. 18, 2014 (JP) 2014-147442

(51) Int. Cl. H05K 7/20; G06F 1/20

(52) U.S. Cl. CPC H05K 7/20336; G06F 1/203

(57) ABSTRACT

According to one embodiment, an electronic apparatus includes a housing, a heat-producing element, a first heat absorber, a second heat absorber and a heat transfer member. The heat-producing element produces heat in the housing. The first heat absorber is provided on an inner surface of the housing to face the heat-producing element. The first heat absorber absorbs heat from the heat-producing element in the housing. The second heat absorber is provided on the inner surface of the housing at a position separate from the first heat absorber. The heat transfer member transfers heat from the heat-producing element absorbed by the first heat absorber to the second heat absorber.

### CROSS-REFERENCE TO RELATED APPLICATIONS

This application is based upon and claims the benefit of priority from Japanese Patent Application No. 2014-147442, filed Jul. 18, 2014, the entire contents of which are incorporated herein by reference.

### FIELD

Embodiments described herein relate generally to an electronic apparatus.

### BACKGROUND

In electronic apparatuses such as tablet computers, housings have been made progressively thinner, for example, to improve operability when being held in one hand by users.

In a slim and compact electronic apparatus, the heat from heat-producing circuit components, for example, a CPU, is likely to be directly conducted to the housing. Since the housing may be held in one hand by a user for long periods, when accommodating the heat-producing circuit components inside the housing, it is necessary to take a measure to suppress a rise of temperature of the housing.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a state where a user holds a tablet computer according to a first embodiment with one hand;

FIG. 2 is an exemplary front view of the tablet computer according to the first embodiment;

FIG. 3 is an exemplary back view of the tablet computer according to the first embodiment;

FIG. 4 is an exemplary cross-sectional view taken along line F4-F4 of FIG. 2;

FIG. 5 is an exemplary cross-sectional view showing an enlarged portion F5 of FIG. 4;

FIG. 6 is an exemplary cross-sectional view showing an enlarged portion F6 of FIG. 4;

FIG. 7 is an exemplary cross-sectional view of a tablet computer according to a second embodiment;

FIG. 8 is an exemplary plan view of a tablet computer according to a third embodiment;

FIG. 9 is an exemplary cross-sectional view showing a structure of a first heat absorber in a forth embodiment; and

FIG. 10 is an exemplary cross-sectional view showing a structure of a second heat absorber in the fourth embodiment.

### DETAILED DESCRIPTION

Various embodiments will be described hereinafter with reference to the accompanying drawings. In general, according to one embodiment, an electronic apparatus comprises a housing, a heat-producing element, a first heat absorber, a second heat absorber and a heat transfer member. The heat-producing element produces heat in the housing. The first heat absorber is provided on an inner surface of the housing to face the heat-producing element. The first heat absorber absorbs heat from the heat-producing element in the housing. The second heat absorber is provided on the inner surface of the housing at a position separate from the first heat absorber. The heat transfer member transfers heat from the heat-producing element absorbed by the first heat absorber to the second heat absorber.

### First Embodiment

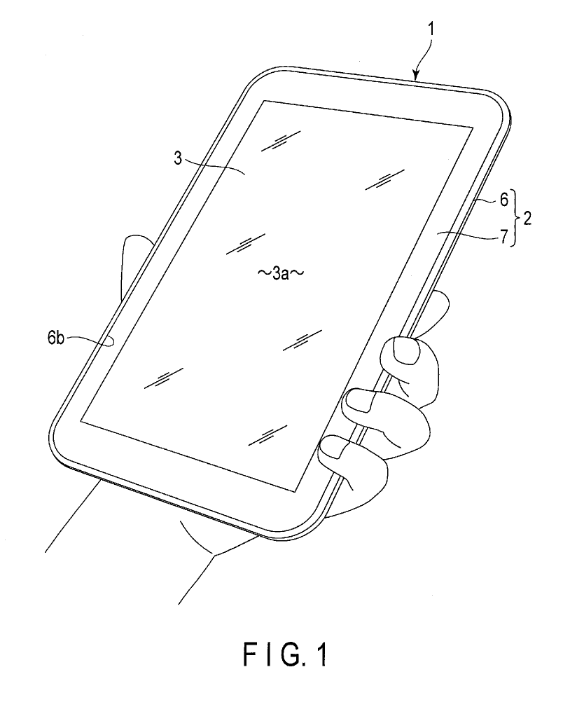

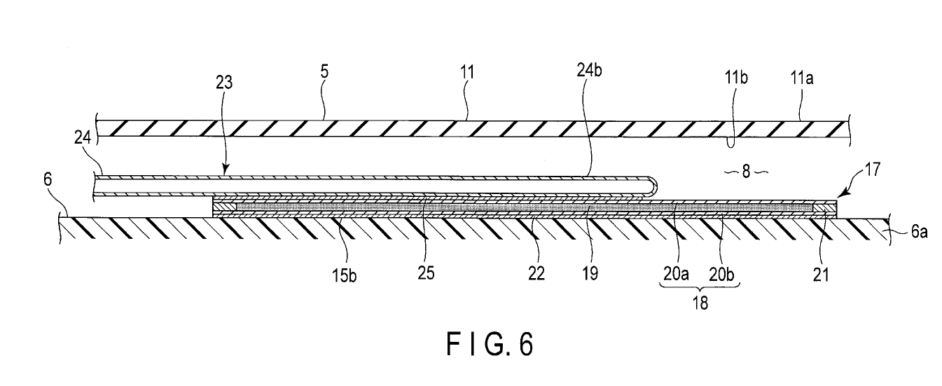

A first embodiment will be hereinafter described with reference to FIG. 1 to FIG. 6.

FIG. 1 discloses a tablet computer 1, which is an example of an electronic apparatus. The tablet computer 1 is of a size that a user can hold and operate with one hand.

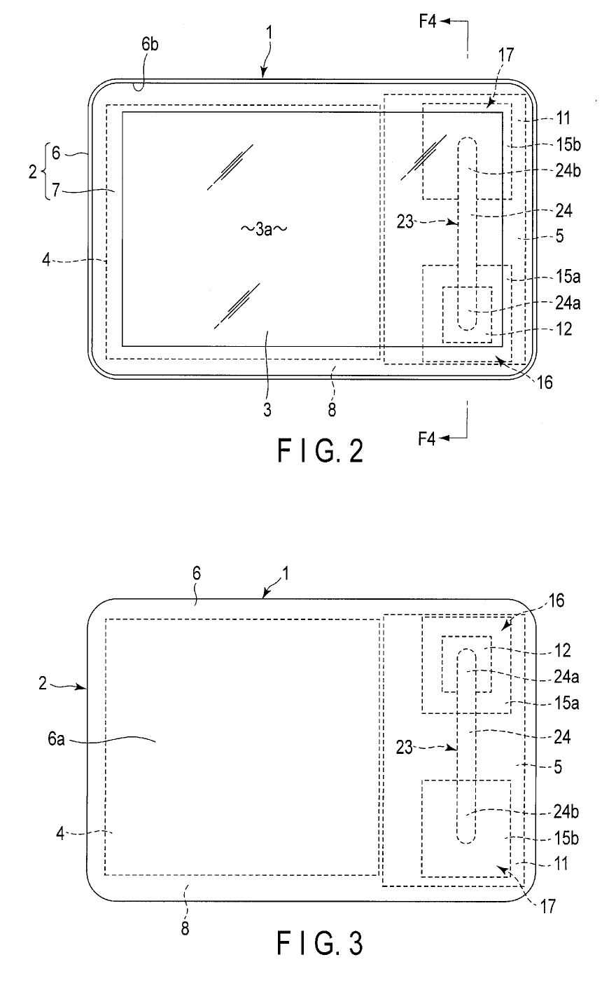

As shown in FIG. 2 to FIG. 4, the tablet computer 1 comprises a housing 2, a liquid crystal display module 3, a battery 4 and a motherboard 5 as main elements. The housing 2 comprises a main body 6 and a protective panel 7. The main body 6 has the shape of a flat quadrilateral box, and is formed of, for example, a synthetic resin material. The main body 6 comprises a bottom wall 6a and a quadrilateral opening portion 6b facing the bottom wall 6a. The bottom wall 6a is a place which is touched by the user's palm when the user holds the tablet computer 1 with one hand.

The protective panel 7 is a quadrilateral plate made of glass or synthetic resin, and is fitted into the opening portion 6b of the main body 6. Between the protective panel 7 and the bottom wall 6a of the main body 6, a mounting space 8 is defined. As shown in FIG. 2 to FIG. 4, the crystal liquid display module 3, the battery 4 and the motherboard 5 are accommodated in the mounting space 8.

The liquid crystal display module 3 comprises a display surface 3a displaying various kinds of information such as an image and a character. The display surface 3a is covered with the protective panel 7. A touch panel 9 having a handwriting input function is interposed between the protective panel 7 and the display surface 3a.

The battery 4 and the motherboard 5 are disposed between the liquid crystal display module 3 and the bottom wall 6a. The motherboard 5 comprises a printed-wiring board 11, a semiconductor package 12 constituting a CPU, and circuit elements 13.

The printed-wiring board 11 comprises a first mounting surface 11a and a second mounting surface 11b. The first mounting surface 11a faces a back surface 3b of the liquid crystal display module 3. The second mounting surface 11b is positioned on a back side of the first mounting surface 11a to face the bottom wall 6a of the housing 2.

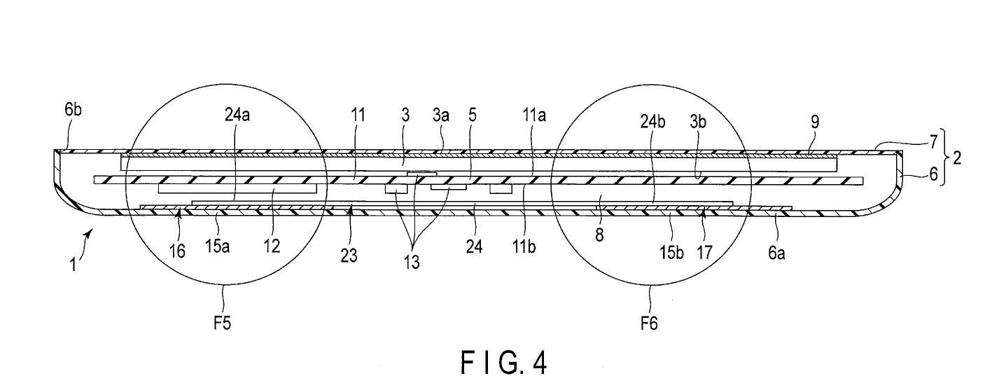

The semiconductor package 12 is an example of a heat-producing element, and produces heat during operation. The semiconductor package 12 can be rephrased as a circuit component that produces heat during operation. As shown in FIG. 4, the semiconductor package 12 is mounted on the second mounting surface 11b of the printed-wiring board 11, and faces an inner surface of the bottom wall 6a of the housing 2. Thus, the bottom wall 6a receives radiant heat emitted by the semiconductor package 12. Moreover, the circuit elements 13 are dispersedly mounted on the first mounting surface 11a and the second mounting surface 11b of the printed-wiring board 11.

As shown in FIG. 4, the inner surface of the bottom wall 6a of the housing 2 comprises a first area 15a and a second area 15b. The first area 15a is positioned directly under the semiconductor package 12 to face the semiconductor package 12. The first area 15a can be rephrased as a high-temperature portion receiving radiant heat emitted from the semiconductor package 12. The second area 15b is separate from the semiconductor package 12. The second area 15b can be rephrased as a low-temperature portion less influenced by radiant heat from the semiconductor package 12 than the first area 15a.

As shown in FIG. 2 to FIG. 4, a sheetlike first heat absorber 16 is stacked on the first area 15a of the bottom wall 6a. Moreover, a sheetlike second heat absorber 17 is stacked on the second area 15b of the bottom wall 6a. The first heat absorber 16 and the second heat absorber 17 each have a shape that is at least to a degree larger than that of the semiconductor package 12.

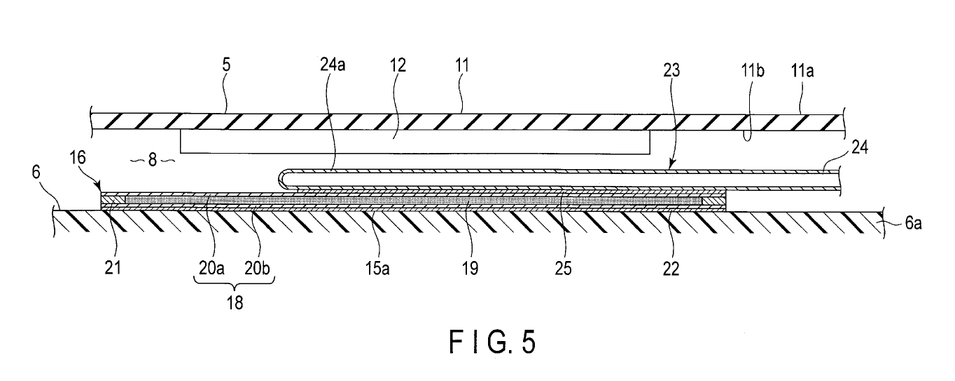

Because the first heat absorber 16 and the second heat absorber 17 have a common structure, the first heat absorber 16 will be described representatively. As shown in FIG. 5, the first heat absorber 16 comprises a package 18 and a phase-change material 19. The package 18 includes, for example, two quadrilateral copper sheets 20a and 20b. The copper sheets 20a and 20b are stacked on each other, and periphery portions thereof are joined continuously in a circumferential direction through an adhesive 21. The adhesive 21 also serves as a spacer securing a gap between the copper sheets 20a and 20b.

The phase-change material 19 is enclosed in the gap between the copper sheets 20a and 20b. The phase-change material 19 is a material changing its state from a solid to a liquid and from a liquid to a solid in accordance with a change in temperature, and for example, polyethylene glycol or paraffin can be used. The phase-change material 19 of this kind requires great latent heat when changing in phase from a solid to a liquid, and thus absorbs ambient heat of fusion. Moreover, the phase-change material 19 gradually returns from a liquid to a solid when the ambient temperature is less than or equal to a phase-change temperature, and emits heat of solidification in this process.

The first heat absorber 16 is fixed on the first area 15a of the bottom wall 6a through a double-sided adhesive tape 22 having thermal conductivity. Similarly, the second heat absorber 17 is fixed on the second area 15b of the bottom wall 6a through a double-sided adhesive tape 22. Thus, the first heat absorber 16 and the second heat absorber 17 are each thermally connected to the bottom wall 6a of the housing 2.

As shown in FIG. 4 to FIG. 6, a heat pipe 23 is laid between the first heat absorber 16 and the second heat absorber 17. The heat pipe 23 is an example of a heat transfer member, and comprises a flat container 24 enclosing a working liquid.

The container 24 comprises a heat-receiving end portion 24a and a heat-emitting end portion 24b. The heat-receiving end portion 24a is positioned at one end of the container 24, and is joined to the package 18 of the first heat absorber 16 through a double-sided adhesive tape 25 having thermal conductivity. Moreover, the heat-receiving end portion 24a is interposed between the semiconductor package 12 and the first heat absorber 16.

The heat-emitting end portion 24b is positioned at the other end of the container 24, and is joined to a package 18 of the second heat absorber 17 through a double-sided adhesive tape 25. The heat pipe 23 is thermally connected to the first heat absorber 16 and the second heat absorber 17 in the state of being separate from the bottom wall 6a.

In such a structure, when the tablet computer 1 is operated by the user, the semiconductor package 12 as a CPU produces heat. Some of the heat emitted by the semiconductor package 12 becomes radiant heat and is transmitted toward the bottom wall 6a of the housing 2.

According to the present embodiment, the first heat absorber 16 is stacked on the first area 15a of the bottom wall 6a which the semiconductor package 12 faces. The first heat absorber 16 receives radiant heat from the semiconductor package 12, and its temperature thereby rises. When the temperature of the first heat absorber 16 reaches the melting point of the phase-change material 19, the phase-change material 19 starts to melt and changes its state from a solid to a liquid. When changing from a solid to a liquid, the phase-change material 19 requires great latent heat. Thus, the phase-change material 19 absorbs radiant heat from the semiconductor package 12 and ambient heat of the semiconductor package 12 inside the housing 2.

Furthermore, heat absorbed by the first heat absorber 16 and radiant heat from the semiconductor package 12 are conducted to the heat-receiving end portion 24a of the heat pipe 23. The working liquid enclosed in the container 24 thereby absorbs heat and evaporates at the heat-receiving end portion 24a. Vaporized working liquid moves from the heat-receiving end portion 24a to the heat-emitting end portion 24b through the inside of the container 24.

The heat-emitting end portion 24b of the heat pipe 23 separate from the semiconductor package 12 is less influenced by heat from the semiconductor package 12, and thus is kept at a lower temperature than the heat-receiving end portion 24a. Thus, if vaporized working liquid is led to the heat-emitting end portion 24b, the vaporized working liquid condenses and emits heat. The working liquid which has emitted heat returns to a liquid. Liquefied working liquid returns from the heat-emitting end portion 24b to the heat-receiving end portion 24a by capillary action, and again receives heat absorbed by the first heat absorber 16 and radiant heat from the semiconductor package 12.

The working liquid repeats evaporation and condensation in this manner, and heat absorbed by the first heat absorber 16 is thereby transferred from the heat-receiving end portion 24a to the heat-emitting end portion 24b of the heat pipe 23.

According to the present embodiment, the heat-emitting end portion 24b of the heat pipe 23 is thermally connected to the second heat absorber 17 stacked on the second area 15b of the bottom wall 6a. As a result, heat emitted from the working liquid when the working liquid condenses at the heat-emitting end portion 24b is absorbed by the second heat absorber 17. Accordingly, a temperature gradient between the heat-receiving end portion 24a and the heat-emitting end portion 24b of the heat pipe 23 can be sufficiently secured, and heat transfer from the heat-receiving end portion 24a to the heat-emitting end portion 24b can be efficiently performed.

According to the first embodiment, because heat emitted by the semiconductor package 12 is absorbed by the first heat absorber 16 on the bottom wall 6a, heat from the semiconductor package 12 can be prevented from being directly conducted to the first area 15a of the bottom wall 6a.

Furthermore, heat from the semiconductor package 12 absorbed by the first heat absorber 16 is actively transferred to the second heat absorber 17 separate from the semiconductor package 12 through the heat pipe 23. The second heat absorber 17 absorbs heat emitted from the heat pipe 23. Heat emitted from the heat pipe 23 can be thereby prevented from being directly conducted to the second area 15b of the bottom wall 6a.

As a result, a heat absorbing effect of the first heat absorber 16 directly under the semiconductor package 12 and heat absorbing effects of heat transfer by the heat pipe 23 and of the second heat absorber 17 at a position separate from the semiconductor package 12 act synergistically, and the bottom wall 6a of the housing 2 can be prevented from being at a high temperature locally.

Therefore, a temperature distribution of the bottom wall 6a is equalized, and the general temperature of the housing 2 can be kept within an appropriate range. By virtue of this, the user does not feel heat, even though the user's palm touches the bottom wall 6a of the housing 2 when holding and operating the tablet computer 1 with one hand. Thus, a comfortable operating environment can be provided.

In addition, according to the first embodiment, because heat from the semiconductor package 12 absorbed by the first heat absorber 16 is transferred to the second heat absorber 17 by the heat pipe 23, the mass of the first heat absorber 16 necessary for the first heat absorber 16 to absorb heat can be reduced. Accordingly, the first heat absorber 16 can be made compact.

On the other hand, for example, when a calorific value of the semiconductor package 12 decreases and the temperatures of the first heat absorber 16 and the second heat absorber 17 decline to freezing points of phase-change materials 19, the phase-change materials 19 change their states from a liquid to a solid. At this time, although heat of solidification is emitted from the phase-change materials 19, heat from the semiconductor package 12 has a small influence on the housing 2 at this point of time, and heat of solidification is slowly emitted from the phase-change materials 19 with much time taken.

Thus, the bottom wall 6a of the housing 2 is prevented from being at a high temperature locally at positions corresponding to the first heat absorber 16 and the second heat absorber 17, and a problem of a temperature rise of the housing 2 does not arise.

In the first embodiment, the housing 2 is not only made of synthetic resin, but may be made of metal, for example, magnesium alloy. Because the thermal conductivity of the housing 2 is improved by making the housing 2 of metal, heat conducted from the first and second heat absorbers 16 and 17 to the bottom wall 6a can be diffused over a wide range of the main body 6. As a result, a heat spot is not formed in the housing 2 and a temperature distribution of the housing 2 can be equalized.

### Second Embodiment

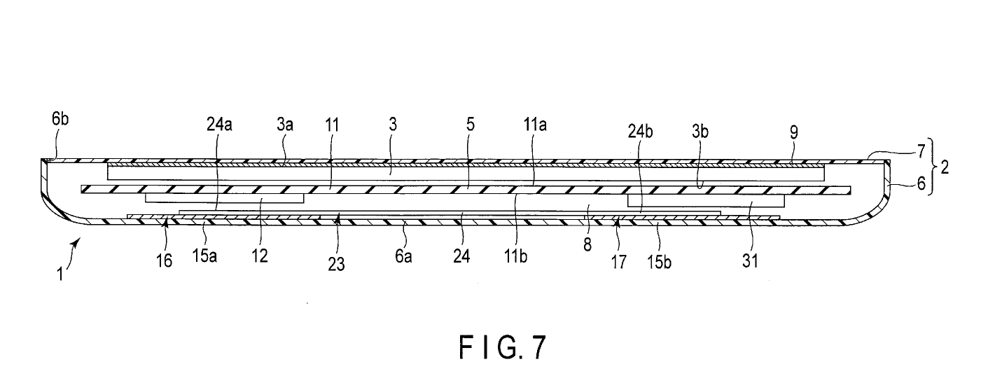

FIG. 7 discloses a second embodiment.

In the second embodiment, a semiconductor package 31 constituting, for example, a graphics chip, is mounted on the second mounting surface 11b of the printed-wiring board 11. The semiconductor package 31 faces the second heat absorber 17. Except for the semiconductor package 31, the structure of the tablet computer 1 is basically the same as in the first embodiment. Accordingly, in the second embodiment, the same structural portions as those of the first embodiment will be given the same reference numbers, and detailed explanations thereof will be omitted.

The semiconductor package 31 is an example of a circuit component that produces heat during operation. In the present embodiment, the two heat-producing semiconductor packages 12 and 31 are arranged to allow a space between them on the second mounting surface 11b of the printed-wiring board 11. The two semiconductor packages 12 and 31 do not operate simultaneously in the housing 2.

Thus, when one semiconductor package 12 produces heat, the other semiconductor package 31 maintains a low-temperature state without producing heat. Similarly, when the other semiconductor package 31 produces heat, the one semiconductor package 12 maintains a low-temperature state without producing heat.

In the second embodiment, when the one semiconductor package 12 produces heat during operation, the phase-change material 19 of the first heat absorber 16 changes its state from a solid to a liquid. The phase-change material 19 thereby absorbs heat from the semiconductor package 12. Heat absorbed by the phase-change material 19 is transferred to the second heat absorber 17 through the hear pipe 23. Heat from the semiconductor package 12 can be thereby prevented from being directly conducted to the first area 15a of the bottom wall 15a.

At this time, because the other semiconductor package 31 facing the second heat absorber 17 is in a nonoperating state in which heat is not emitted, the second heat absorber 17 and the heat-emitting end portion 24b of the heat pipe 23 do not receive heat from the semiconductor package 31.

Accordingly, a temperature gradient between the heat receiving end portion 24a and the heat-emitting end portion 24b of the heat pipe 23 is sufficiently secured, and heat from the semiconductor package 12 absorbed by the first heat absorber 16 is actively transferred to the second heat absorber 17 through the heat pipe 23. Because the second heat absorber 17 absorbs heat emitted from the heat-emitting end portion 24b of the heat pipe 23, heat emitted from the heat pipe 23 can be prevented from being directly conducted to the second area 15b of the bottom wall 6a.

When the other semiconductor package 31 operates, the one semiconductor package 12 is in a nonoperating state, and does not emit heat. Thus, the phase-change material 19 of the first heat absorber 16 assumes the state of a solid.

When the other semiconductor package 31 produces heat during operation, the phase-change material 19 of the second heat absorber 17 changes its state from a solid to a liquid. The phase-change material 19 thereby absorbs heat from the other semiconductor package 31. Heat absorbed by the phase-change material 19 is transferred to the first heat absorber 16 through the heat pipe 23. Heat from the other semiconductor package 31 can be thereby prevented from being directly conducted to the second area 15b of the bottom wall 6a.

At this time, because the one semiconductor package 12 facing the first heat absorber 16 is in a nonoperating state in which heat is not emitted, the first heat absorber 16 does not receive heat from the one semiconductor package 12. Therefore, the relationship between the heat-receiving end portion 24a and the heat-emitting end portion 24b of the heat pipe 23 is reversed, and a temperature gradient between the heat-receiving end portion 24a and the heat-emitting end portion 24b can be sufficiently secured.

Thus, heat from the semiconductor package 31 absorbed by the second heat absorber 17 is actively transferred to the first heat absorber 16 through the heat pipe 23. Because the first heat absorber 16 absorbs heat emitted from the heat pipe 23, heat emitted from the heat pipe 23 can be prevented from being directly conducted to the first area 15a of the bottom wall 6a.

For this reason, by thermally connecting the first heat absorber 16 disposed directly under the one semiconductor package 12 and the second heat absorber 17 disposed directly under the other semiconductor package 31 by the heat pipe 23, the bottom wall 6a of the housing 2 can be prevented from being at a high temperature locally.

Therefore, the user does not feel heat, even though the user's palm touches the bottom wall 6a of the housing 2 when holding and operating the tablet computer 1 with one hand.

### Third Embodiment

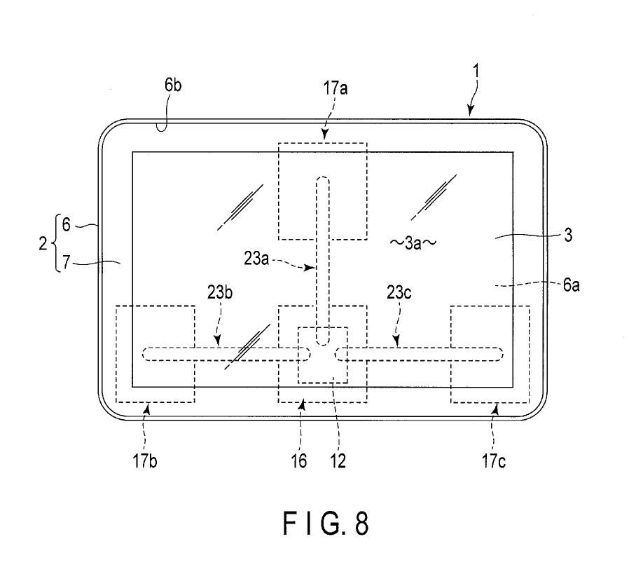

FIG. 8 discloses a third embodiment.

In the third embodiment, second heat absorbers 17a, 17b and 17c are disposed at positions separate from the first heat absorber 16. The second heat absorbers 17a, 17b and 17c are dispersedly disposed around the first heat absorber 16 on the inner surface of the bottom wall 6a. Moreover, the first heat absorber 16 and the second heat absorbers 17a, 17b and 17c are thermally connected by heat pipes 23a, 23b and 23c.

According to the third embodiment, the phase-change material 19 of the first heat absorber 16 changes its state from a solid to a liquid, and thus heat emitted by the semiconductor package 12 is absorbed by the phase-change material 19. Heat absorbed by the first heat absorber 16 is transferred to the second heat absorbers 17a, 17b and 17c through the heat pipes 23a, 23b and 23c. The second heat absorbers 17a, 17b and 17c individually absorb heat emitted from the heat pipes 23a, 23b and 23c.

According to such a structure, because heat from the semiconductor package 12 absorbed by the first heat absorber 16 is dispersed to the second heat absorbers 17a, 17b and 17c, heat emitted by the semiconductor package 12 can be diffused over a wide range of the main body 6. Thus, the structure is advantageous in equalizing a temperature distribution of the housing 2.

### Fourth Embodiment

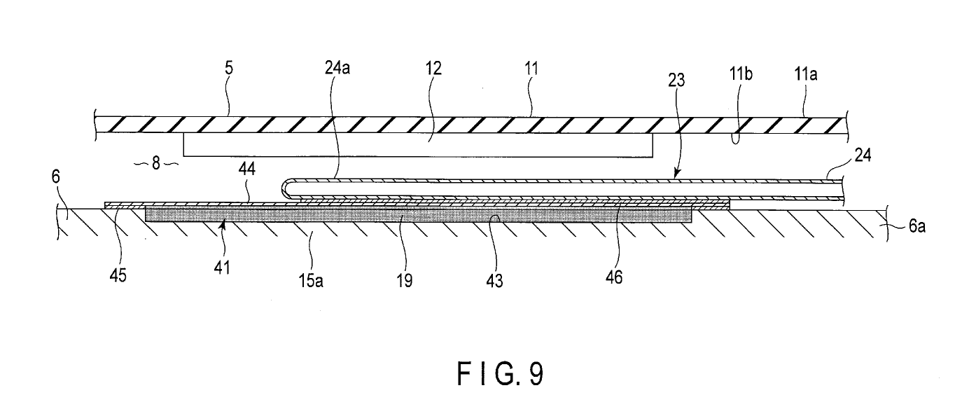

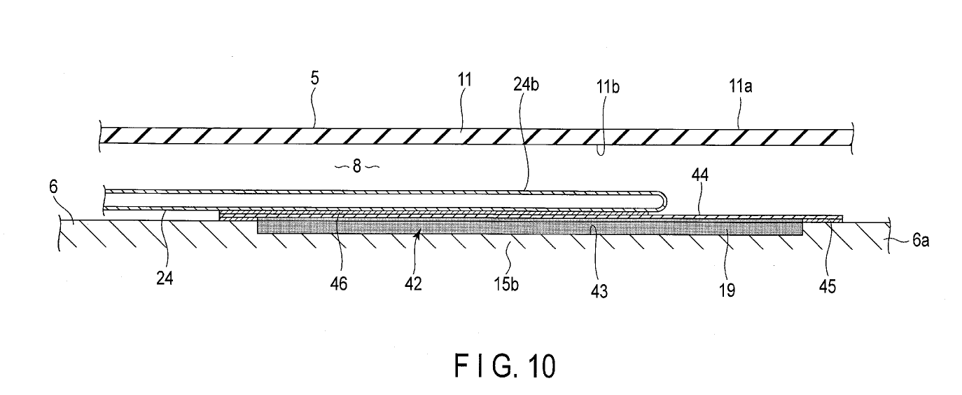

FIG. 9 and FIG. 10 disclose a fourth embodiment.

In the fourth embodiment, a structure for absorption of heat from the semiconductor package 12 differs from that of the first embodiment. Except for this, the structure of the tablet computer 1 is basically the same as in the first embodiment. Accordingly, in the fourth embodiment, the same structural portions as those of the first embodiment will be given the same reference numbers, and detailed explanations thereof will be omitted.

The main body 6 of the housing 2 is composed of a metal, for example, magnesium alloy. The main body 6 made of metal has better thermal conductivity than a main body made of synthetic resin. As shown in FIG. 9 and FIG. 10, a first heat absorber 41 and a second heat absorber 42 are formed on the bottom wall 6a of the main body 6. The first heat absorber 41 is positioned at the first area 15a of the bottom wall 6a. The second heat absorber 42 is positioned at the second area 15b of the bottom wall 6a. Because the first heat absorber 41 and the second heat absorber 42 have a common structure, the first heat absorber 41 will be described representatively.

As shown in FIG. 9, the first heat absorber 41 includes a depression 43. The depression 43 is formed on the inner surface of the bottom wall 6a to be positioned directly under the semiconductor package 12. The depression 43 has an opening shape at least to a degree larger than the semiconductor package 12.

The depression 43 is filled with a phase-change material 19, for example, polyethylene glycol or paraffin. The phase-change material 19 absorbs ambient heat of fusion when changing in phase from a solid to a liquid, and emits heat of solidification in the process of changing in phase from a liquid to a solid.

Furthermore, the depression 43 filled with the phase-change material 19 is covered by a thermally conductive sheet 44, for example, a copper sheet. A periphery portion of the thermally conductive sheet 44 is joined to the inner surface of the bottom wall 6a through a thermally conductive adhesive 45. Thus, the thermally conductive sheet 44 seals the depression 43 with the phase-change material 19. In other words, the phase-change material 19 is enclosed in a gap between an inner surface of the depression 43 and the thermally conductive sheet 44, and is thermally connected to both of the bottom wall 6a and the thermally conductive sheet 44.

As shown in FIG. 9 and FIG. 10, the heat pipe 23 is laid between the first heat absorber 41 and the second heat absorber 42. The heat pipe 23 comprises the flat container 24 enclosing a working liquid.

The heat-receiving end portion 24a of the container 24 is joined to the thermally conductive sheet 44 of the first heat absorber 41 through a double-sided adhesive tape 46 having thermal conductivity. The heat-receiving end portion 24a is interposed between the semiconductor package 12 and the first heat absorber 41.

The heat-emitting end portion 24b of the container 24 is joined to a thermally conductive sheet 44 of the second heat absorber 42 through a double-sided adhesive tape 46. Thus, the heat pipe 23 is thermally connected to the first heat absorber 41 and the second heat absorber 42.

In such a structure, when the semiconductor package 12 produces heat, some of the heat becomes radiant heat and is transmitted toward the bottom wall 6a of the housing 2. According to the present embodiment, the first heat absorber 41 is formed on the first area 15a of the bottom wall 6a which the semiconductor package 12 faces. The first heat absorber 41 receives radiant heat from the semiconductor package 12, and its temperature thereby rises.

When the temperature of the first heat absorber 41 reaches the melting point of the phase-change material 19, the phase-change material 19 starts to melt and changes its state from a solid to a liquid. When changing from a solid to a liquid, the phase-change material 19 absorbs radiant heat from the semiconductor package 12 and ambient heat of the semiconductor package 12.

Furthermore, heat absorbed by the first heat absorber 41 and radiant heat from the semiconductor package 12 are conducted to the heat-receiving end portion 24a of the heat pipe 23. The working liquid enclosed in the container 24 thereby absorbs heat and evaporates at the heat-receiving end portion 24a. Vaporized working liquid moves from the heat-receiving end portion 24a to the heat-emitting end portion 24b through the inside of the container 24.

The heat-emitting end portion 24b of the heat pipe 23 separate from the semiconductor package 12 is kept at a lower temperature than the heat-receiving end portion 24a. Thus, vaporized working liquid led to the heat-emitting end portion 24b condenses and emits heat. The working liquid which has emitted heat returns to a liquid. Liquefied working liquid returns from the heat-emitting end portion 24b to the heat-receiving end portion 24a by capillary action, and again receives heat absorbed by the first heat absorber 41 and radiant heat from the semiconductor package 12.

The working liquid repeats evaporation and condensation in this manner, and heat absorbed by the first heat absorber 41 is thereby transferred to the heat-emitting end portion 24b of the heat pipe 23.

According to the present embodiment, the heat-emitting end portion 24b of the heat pipe 23 is thermally connected to the second heat absorber 42 formed on the second area 15b of the bottom wall 6a. As a result, heat emitted from the working liquid when the working liquid condenses at the heat-emitting end portion 24b is absorbed by a phase-change material 19 of the second heat absorber 42. Therefore, a temperature gradient between the heat-receiving end portion 24a and the heat-emitting end portion 24b of the heat pipe 23 can be sufficiently secured, and heat transfer from the heat-receiving end portion 24a to the heat-emitting end portion 24b can be efficiently performed.

According to the fourth embodiment, because heat emitted by the semiconductor package 12 is absorbed by the first heat absorber 41 of the bottom wall 6a, heat from the semiconductor package 12 can be prevented from being directly conducted to the first area 15a of the bottom wall 6a.

Furthermore, heat from the semiconductor package 12 absorbed by the first heat absorber 41 is actively transferred to the second heat absorber 42 separate from the semiconductor package 12 through the heat pipe 23, and the second heat absorber 42 absorbs heat emitted from the heat pipe 23. Thus, heat emitted from the heat pipe 23 can be prevented from being directly conducted to the second area 15b of the bottom wall 6a.

As a result, a heat absorbing effect of the first heat absorber 41 directly under the semiconductor package 12 and heat absorbing effects of heat transfer by the heat pipe 23 and of the second heat absorber 42 at a position separate from the semiconductor package 12 act synergistically, and the bottom wall 6a of the housing 2 can be prevented from being at a high temperature locally.

In particular, in the fourth embodiment, the main body 6 of the housing 2 is composed of metal having better thermal conductivity than synthetic resin. Thus, heat conducted from the phase-change materials 19 of the first heat absorber 41 and the second heat absorber 42 to the bottom wall 6a of the main body 6 is widely diffused throughout the main body 6. Thus, a temperature distribution of the main body 6 can be equalized, and a heat spot is not formed in the main body 6.

In addition, because depressions 43 formed on the bottom wall 6a are filled with the phase-change materials 19, the phase-change materials 19 can be made within a range of thickness of the bottom wall 6a. In other words, the first heat absorber 41 and the second heat absorber 42 take the form of being embedded inside the bottom wall 6a. Therefore, although having the structure in which the first heat absorber 41 and the second heat absorber 42 are added to the bottom wall 6a, thinness of the housing 2 is not spoilt.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, an electronic apparatus is not limited to a tablet computer, but can be similarly implemented by a cellular phone or a smartphone which a user holds and operates with one hand.

What is claimed is:

1. An electronic apparatus comprising:
a housing;
a heat-producing element in the housing;
a first heat absorber configured to absorb heat from the heat-producing element, the first heat absorber located on an inner surface of the housing facing the heat-producing element;
a second heat absorber configured to absorb heat in the housing, the second heat absorber located on the inner surface of the housing at a separate position from the first heat absorber; and
a heat transfer member configured to transfer heat absorbed by the first heat absorber to the second heat absorber.

2. The electronic apparatus of claim 1, wherein each of the first heat absorber and the second heat absorber encloses a package comprising a phase-change material configured to absorb heat by changing phase from a solid to a liquid, the phase-change material has thermal conductivity.

3. The electronic apparatus of claim 2, wherein the package is thermally connected to the housing.

4. The electronic apparatus of claim 1, wherein
the heat transfer member is a heat pipe,
a heat-receiving end portion of the heat pipe is thermally joined to the first heat absorber, and
a heat-emitting end portion of the heat pipe is thermally joined to the second heat absorber.

5. The electronic apparatus of claim 1, wherein the first heat absorber and the second heat absorber are thermally connected to the housing.

6. The electronic apparatus of claim 1, wherein the first heat absorber and the second heat absorber each has a shape larger than the heat-producing element.

7. An electronic apparatus comprising:
a housing;
multiple circuit components in the housing, the circuit components configured to operate not simultaneously, and thereby limit heat produced during operation;
multiple heat absorbers on an inner surface of the housing, each of the heat absorbers corresponding to each of the circuit components, and the heat absorbers configured to absorb heat from the circuit components; and
a heat transfer member configured to transfer heat between the heat absorbers.

8. The electronic apparatus of claim 7, wherein
the heat absorbers each encloses a package comprising a phase-change material configured to absorb heat by changing phase from a solid to a liquid, the phase-change material has thermal conductivity, and the package is thermally connected to the housing.

9. The electronic apparatus of claim 7, wherein
the heat transfer member is a heat pipe,
one end portion of the heat pipe is thermally joined to one of the heat absorbers, and
the other end portion of the heat pipe is thermally joined to one of the other heat absorbers.

10. An electronic apparatus comprising:
a housing;
a heat-producing element configured to produce heat in the housing; and
multiple heat absorbers in the housing, one of the heat absorbers located at an area corresponding to the heat-producing element and the other heat absorbers located at areas, separate from the heat-producing element;
wherein the heat absorbers comprise:
depressions on the inner surface of the housing;
phase-change materials filled in the depressions, the phase-change materials configured to absorb heat by changing phase from a solid to a liquid; and
thermally conductive sheets configured to seal the depressions, and
the heat absorbers are thermally connected through a heat transfer member.

11. The electronic apparatus of claim 10, wherein the housing is made of metal.

12. The electronic apparatus of claim 10, wherein
the heat transfer member is a heat pipe,
a heat-receiving end portion of the heat pipe is thermally connected to the heat absorber corresponding to the heat-producing element, and
a heat-emitting end portion of the heat pipe is thermally connected to the heat absorber separate from the heat-producing element.
